(19) United States
(12) Patent Application Publication
(10) Pub. No.: US 2023/0107154 A1
(43) Pub. Date: Apr. 6, 2023

(54) MAINTENANCE METHOD AND HEAT TREATMENT APPARATUS

(71) Applicant: SHIBAURA MECHATRONICS CORPORATION, Kanagawa (JP)

(72) Inventors: Junji ISHIHARA, Kanagawa (JP); Akinori ISO, Kanagawa (JP); Hirokazu MASUDA, Kanagawa (JP)

(21) Appl. No.: 17/951,716

(22) Filed: Sep. 23, 2022

(30) Foreign Application Priority Data
Sep. 27, 2021 (JP) 2021156921

(51) Int. Cl. B05D 3/04; B05D 3/06; B05C 13/00

(52) U.S. Cl. CPC B05D 3/048; B05D 3/06; B05C 13/00; B05D 1/60

(57) ABSTRACT

Provided is a maintenance method of a heat treatment apparatus including a chamber having a box shape and provided with a heater and a receiving member that supports a cassette having a box shape including a space in which a workpiece is supported. The maintenance method includes: attaching a loading/unloading jig including a roller on an upper portion and capable of moving the roller upward and downward, to the receiving member; transmitting the cassette supported by the receiving member onto the roller by raising the loading/unloading jig; unloading the cassette to an outside of the chamber by moving the cassette on the roller; loading the cassette into the chamber by moving the cassette on the roller; transmitting the cassette to the receiving member by lowering the loading/unloading jig; and detaching the loading/unloading jig from the receiving member.

### CROSS-REFERENCE TO RELATED APPLICATIONS

This application is based on and claims priority from Japanese Patent Application No. 2021-156921, filed on Sep. 27, 2021 with the Japan Patent Office, the disclosure of which is incorporated herein in its entirety by reference.

### TECHNICAL FIELD

Embodiments of the present disclosure relate to a maintenance method and a heat treatment apparatus.

### BACKGROUND

There is a heat treatment apparatus that heats a workpiece to form a film on the surface of the workpiece or process the surface of the workpiece.

For example, a heat treatment apparatus has been proposed including a processing container in which a workpiece is held, a plate member provided inside the processing container to face a surface of the workpiece, another plate member provided inside the processing container to face a back surface of the workpiece, a plurality of heaters provided on the upper side and the lower side of the processing container, and a load-lock chamber connected to the processing container.

According to the heat treatment apparatus, the workpiece may be heated not only from the surface side but also from the back surface side, and thus, the processing time may be shortened.

Further, since the plate member facing the surface of the workpiece is provided inside the processing container, heat from a plurality of heaters may be incident on the plate member. The heat incident on the plate member is incident on the surface of the workpiece while being transferred in the surface direction of the plate member.

Further, since the plate member facing the back surface of the workpiece is provided inside the processing container, heat from a plurality of heaters may be incident on the plate member. The heat incident on the plate member is incident on the back surface of the workpiece while being transferred in the surface direction of the plate member.

As a result, during the heat treatment, the variations in the in-plane distribution of the temperature of the surface of the workpiece and the temperature of the back surface of the workpiece may be suppressed from occurring. As a result, the variations in the in-plane distribution of the quality of the formed film or the processed layer may be suppressed from occurring.

During the heat treatment, a sublimated product (e.g., gas) may be released from the workpiece. The released sublimated product may be turned into a solid and attached to the plate member or to an inner wall of the processing container. As a result, a maintenance to remove the sublimated product (e.g., solid) is required as necessary or regularly.

However, the plate member is fixed inside the processing container, and the processing container is fixed to the load-lock chamber. As a result, when removing the sublimated product, it is necessary to disassemble and assemble these elements, and thus, the time and the labor required for the maintenance become excessive. Further, while performing the maintenance for removing the sublimated product, the heat treatment apparatus may not be operated.

Therefore, it has been required to develop a technique capable of promoting facilitation of the maintenance.

### SUMMARY

The present disclosure is to provide a maintenance method and a heat treatment apparatus.

An aspect of the present disclosure provides a maintenance method of a heat treatment apparatus including a chamber having a box shape and provided with a heater and a receiving member that supports a cassette having a box shape including a space in which a workpiece is supported. The maintenance method includes: attaching a loading/unloading jig including a roller on an upper portion and capable of moving the roller upward and downward, to the receiving member; transmitting the cassette supported by the receiving member onto the roller by raising the loading/unloading jig; unloading the cassette to an outside of the chamber by moving the cassette on the roller; loading the cassette into the chamber by moving the cassette on the roller; transmitting the cassette to the receiving member by lowering the loading/unloading jig; and detaching the loading/unloading jig from the receiving member.

According to the embodiment of the present disclosure, a maintenance method and a heat treatment apparatus are provided.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic front view illustrating a heat treatment apparatus according to an embodiment.

FIG. 2 is a schematic cross-sectional view taken along a line A-A direction in the heat treatment apparatus in FIG. 1.

FIG. 3 is a schematic perspective view of a chamber and a cassette rack.

FIG. 4 is a schematic perspective view illustrating an exterior of the cassette.

FIG. 5 is a schematic perspective view illustrating an inside of the cassette.

FIG. 6 is a schematic view illustrating a portion where a receiving member of a frame of the cassette rack is provided.

FIG. 7 is a schematic perspective view illustrating a loading/unloading jig used to load or unload the cassette to or from the chamber.

FIG. 8 is a schematic perspective view illustrating a driving unit of the loading/unloading jig.

FIG. 9 is a schematic cross-sectional view illustrating a lifting unit connected to the driving unit of the loading/unloading jig.

FIG. 10 is a schematic cross-sectional view illustrating a lifting unit connected between connecting units.

FIG. 11 is a schematic exploded view of a block in FIG. 10 viewed in Y-direction.

FIG. 12 is a schematic cross-sectional view illustrating the connecting unit connected between the lifting units.

FIG. 13 is a schematic side view of a cover and a shaft of the connecting unit.

FIG. 14 is a schematic view illustrating a state of the lifting unit in a case where the loading/unloading jig is at a lowered end.

FIG. 15 is a schematic view illustrating a state of the lifting unit in a case where the loading/unloading jig is at a raised end.

FIG. 16 is a schematic view illustrating a method for loading/unloading a cassette.

FIG. 17 is a schematic view illustrating a method for loading/unloading a cassette.

FIG. 18A is a schematic perspective view illustrating an inside of a cassette according to another embodiment. FIG. 18B is an enlarged view of a portion B in FIG. 18A.

### DESCRIPTION OF EMBODIMENTS

In the following detailed description, reference is made to the accompanying drawings, which form a part hereof. The illustrative embodiments described in the detailed description, drawings, and claims are not meant to be limiting. Other embodiments may be utilized, and other changes may be made, without departing from the spirit or scope of the subject matter presented here.

Hereinafter, the embodiments will be described with reference to the drawings. In each drawing, the same reference numerals are given to the same components, and detailed description thereof will be omitted as appropriate.

In the following, descriptions will be made on, as an example, a heat treatment apparatus that heats a workpiece in an atmosphere decompressed below atmospheric pressure to form an organic film on the surface of the workpiece. However, the present disclosure is not limited thereto. For example, the present disclosure may be applied to a heat treatment apparatus that heats a workpiece to form an inorganic film on the surface of the workpiece or process the surface of the workpiece by heating the workpiece.

Further, the workpiece before being heated may include, for example, a substrate and a solution applied to the surface of the substrate, or may include only the substrate. In the following, descriptions will be made on, as an example, a case where the workpiece before being heated includes a substrate and a solution applied to the surface of the substrate.

The solution includes a semi-cured state (non-flowing state) obtained by calcining a liquid.

A workpiece 100 before being heat-treated by a heat treatment apparatus 1 according to an embodiment includes a substrate and a solution applied to the surface of the substrate.

The substrate is, for example, a glass substrate or a semiconductor wafer. However, the substrate is not limited to those illustrated.

The solution contains, for example, an organic material and a solvent. The organic material is not particularly limited as long as it can be dissolved by the solvent. The solution may be, for example, a varnish containing polyamic acid. However, the solution is not limited to those illustrated.

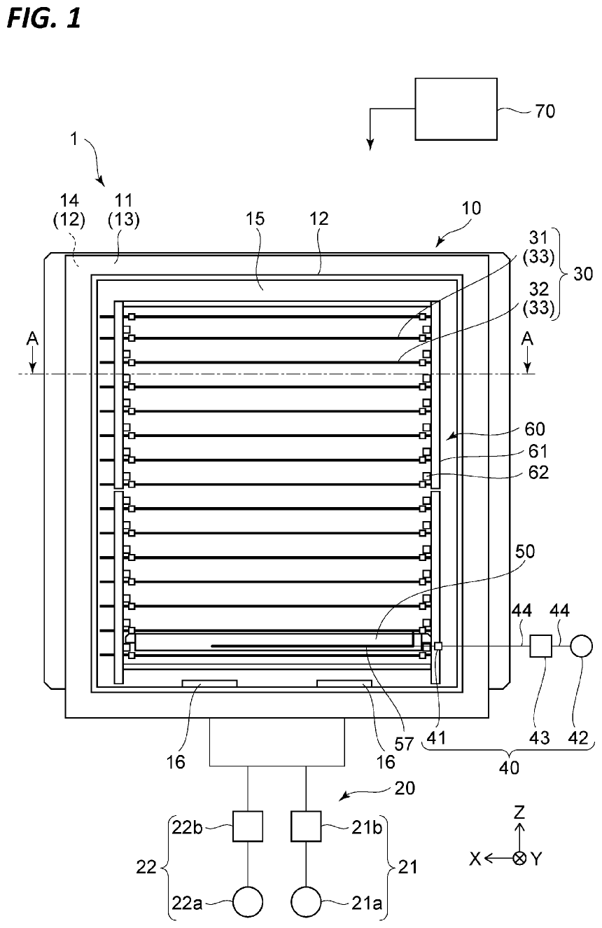

FIG. 1 is a schematic front view illustrating the heat treatment apparatus 1 according to the embodiment.

In FIG. 1, one cassette 50 is illustrated to avoid complexity.

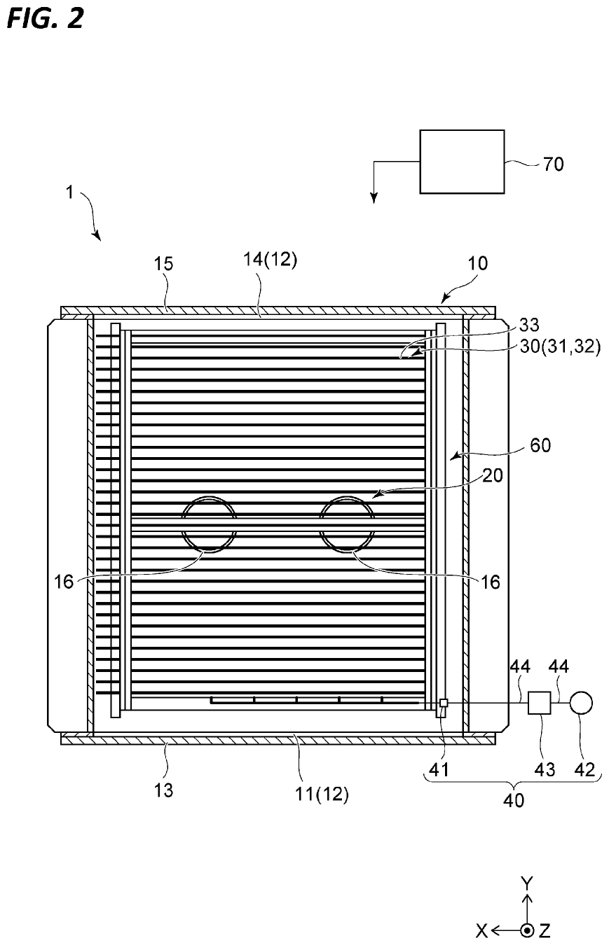

FIG. 2 is a schematic cross-sectional view taken along a line A-A direction in the heat treatment apparatus 1 in FIG. 1.

In FIG. 2, the cassette 50 is omitted to avoid complexity.

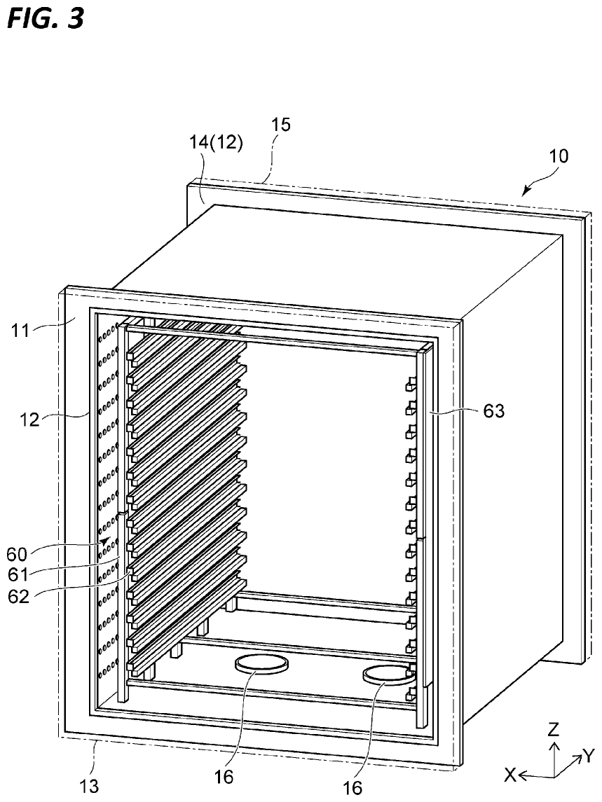

FIG. 3 is a schematic perspective view of a chamber 10 and a cassette rack 60.

The X-direction, the Y-direction, and the Z-direction in each drawing indicate three directions that are orthogonal to each other. In this specification, the vertical direction may be the Z-direction.

As illustrated in FIGS. 1 and 2, the heat treatment apparatus 1 includes, for example, the chamber 10, an exhaust unit 20, a heating unit 30, a cooling unit 40, the cassette 50, the cassette rack 60, and a controller 70.

The controller 70 includes, for example, a processing unit such as a central processing unit (CPU) and a storage unit such as a memory. The controller 70 is, for example, a computer. The controller 70 controls, for example, an operation of each element provided in the heat treatment apparatus 1, based on a control program stored in the storage unit.

As illustrated in FIGS. 1 to 3, the chamber 10 has a box shape. The chamber 10 has an air-tight structure capable of maintaining an atmosphere decompressed below atmospheric pressure. The exterior shape of the chamber 10 is not particularly limited. The exterior shape of the chamber 10 may be, for example, a rectangular parallelepiped or a cylinder. The chamber 10 may be made of, for example, metal such as stainless steel.

For example, an opening is provided at both ends of the chamber 10 in the Y-direction. A flange 11 is provided at one end portion of the chamber 10 in the Y-direction. A sealing member 12 such as an 0-ring is provided in the flange 11. An opening/closing door 13 is provided on the side of the chamber 10 on which the flange 11 is provided. When the opening/closing door 13 is closed, the opening of the chamber 10 is air-tightly closed by the sealing member 12. When the opening/closing door 13 is opened, the workpiece 100 may be loaded or unloaded through the opening at the one end of the chamber 10.

For example, a flange 14 is provided at the other end portion of the chamber 10 in the Y-direction. The sealing member 12 is provided in the flange 14. A lid 15 is provided on the side of the chamber 10 on which the flange 14 is provided. For example, the lid 15 may be attachably/detachably provided in the flange 14 using a fastening member such as a screw. When the lid 15 is mounted, the opening of the chamber 10 is air-tightly closed by the sealing member 12. When the lid 15 that is attachable/detachable is provided, maintenance from the side of the heat processing apparatus 1 on which the flange 14 is provided is facilitated. Further, when the lid 15 is opened for the maintenance, the cassette 50 having a processing space in which the workpiece 100 is heated is loaded into the chamber 10 through the opening at the other end portion of the chamber 10. Further, the cassette 50 is unloaded from the outside of the chamber 10 through the opening at the other end portion of the chamber 10. Here, the cassette 50 and the loading/unloading of the cassette 50 will be described in detail later.

Further, a cooling device (not illustrated) may be provided on an outer wall of the chamber 10. The cooling device may be, for example, a water jacket. When the cooling device is provided, the temperature of the outer wall of the chamber 10 is suppressed from becoming higher than a predetermined temperature.

The exhaust unit 20 exhausts the inside of the chamber 10.

As illustrated in FIG. 1, the exhaust unit 20 includes a first exhaust unit 21 and a second exhaust unit 22. The first exhaust unit 21 and the second exhaust unit 22 are connected to an exhaust port 16 provided in a bottom surface of the chamber 10.

The first exhaust unit 21 includes an exhaust pump 21a and a pressure controller 21b.

The exhaust pump 21a may be an exhaust pump that performs a roughing exhaust from atmospheric pressure to a predetermined pressure. As a result, the exhaust amount of the exhaust pump 21a is larger than that of an exhaust pump 22a (to be described later). The exhaust pump 21a may be, for example, a dry vacuum pump.

The pressure controller 21b is provided between the exhaust port 16 and the exhaust pump 21a. The pressure controller 21b controls the internal pressure of the chamber 10 to a predetermined pressure, based on the output of a vacuum meter (not illustrated) that detects the internal pressure of the chamber 10. The pressure controller 21b may be, for example, an auto pressure controller (APC).

The second exhaust unit 22 includes an exhaust pump 22a and a pressure controller 22b.

The exhaust pump 22a exhausts to a predetermined pressure, which is further low, after the roughing exhaust by the exhaust pump 21a. The exhaust pump 22a has, for example, an exhaust capability capable of exhausting to a high-vacuum molecular flow region. For example, the exhaust pump 22a may be a turbo molecular pump (TMP).

The pressure controller 22b is provided between the exhaust port 16 and the exhaust pump 22a. The pressure controller 22b controls the internal pressure of the chamber 10 to a predetermined pressure, based on the output of a vacuum meter (not illustrated) that detects the internal pressure of the chamber 10. The pressure controller 22b may be, for example, an APC.

The exhaust port 16 is placed in the bottom surface of the chamber 10. As a result, by exhausting the inside of the chamber 10 by the first exhaust unit 21 or the second exhaust unit 22, down-flow airflow toward the bottom surface of the chamber 10 is formed inside the chamber 10. When the down-flow airflow is formed, a sublimated product generated when the workpiece 100 is heated, and containing an organic material is discharged to the outside of the chamber 10 along with the down-flow airflow. As a result, the foreign substance such as the sublimated product may be suppressed from being attached to the inner wall of the chamber 10.

In the above, a case where the exhaust port 16 is provided in the bottom surface of the chamber 10 is illustrated, but the exhaust port 16 may be provided, for example, in a ceiling surface of a side surface of the chamber 10. When the exhaust port 16 is provided in the bottom surface or the ceiling surface of the chamber 10, the airflow toward the bottom surface or the ceiling surface of the chamber 10 may be formed inside the chamber 10.

When the pressure of the internal space of the chamber 10 is decompressed, the heat radiated to the outside of the chamber 10 may be suppressed. As a result, the heating efficiency and the heat storage efficiency may be improved, and thus, a power applied to a heater 33 (to be described later) (corresponding to an example of a first heater and a second heater) may be reduced. When it is possible to reduce the power applied to the heater 33, the load of the heater 33 may be suppressed from being increased. As a result, the lifespan of the heater 33 may be lengthened.

The heating unit 30 includes, for example, a first heating unit 31 and a second heating unit 32. The first heating unit 31 and the second heating unit 32 are provided inside the chamber 10.

The first heating unit 31 is provided above the cassette 50. The first heating unit 31 is provided, for example, above a pair of receiving members 62 (to be described later). Details of the cassette 50 will be described later.

The second heating unit 32 is provided below the cassette 50. The second heating unit 32 is provided, for example, below the pair of receiving members 62 (to be described later). The second heating unit 32 faces the first heating unit 31.

As will be described later, the workpiece 100 is supported inside the cassette 50. As a result, the first heating unit 31 heats the surface (upper surface) of the workpiece 100 supported inside the cassette 50. The second heating unit 32 heats the back surface (lower surface) of the workpiece 100 supported inside the cassette 50.

For example, a plurality of cassettes 50 may be provided to be arranged in the Z-direction (vertical direction) inside the chamber 10. In this case, the second heating unit 32 provided below the upper cassette 50 may be the first heating unit 31 provided above the lower cassette 50. That is, the first heating unit 31 or the second heating unit 32 provided between the cassette 50 and the cassette 50 may be used in both ways.

In this case, the back surface of the workpiece 100 supported inside the upper cassette 50 is heated by the first heating unit 31 or the second heating unit 32 that are used in both ways. The surface of the workpiece 100 supported inside the lower cassette 50 is heated by the first heating unit 31 or the second heating unit 32 that are used in both ways. In this manner, the number of the first heating units 31 and the second heating units 32 may be reduced. Therefore, power consumption may be reduced, manufacturing costs may be reduced, and space may be saved.

The first heating unit 31 includes at least one heater 33. The second heating unit 32 includes at least one heater 33. The heater 33 is held on, for example, the cassette rack 60 (to be described later). An end portion of the heater 33 on the terminal side is exposed to the outside from the side surface of the chamber 10. In this manner, the maintenance of the heater 33 is facilitated. Further, when the workpiece 100 is heated in an atmosphere decompressed below atmospheric pressure, the danger of vacuum discharge at the end portion of the heater 33 on the terminal side may be suppressed.

The first heating unit 31 and the second heating unit 32 according to the embodiment illustrated in FIGS. 1 and 2 include a plurality of heaters 33. For example, the plurality of heaters 33 extend in the X-direction, and are arranged in the Y-direction. The plurality of heaters 33 may extend in the Y-direction, and may be arranged in the X-direction. The plurality of heaters 33 may be arranged at the same intervals, or the intervals may be varied according to the in-plane distribution of the temperature of the workpiece 100. Further, the specifications, the number, or the intervals of the heaters 33 provided in the second heating unit 32 may be the same as, or different from the specifications, the number, or the intervals of the heaters 33 provided in the first heating unit 31. The specifications, the number, or the intervals of the heaters 33 may be appropriately changed according to the composition of the solution to be heated (heating temperature of the solution) or the size of the workpiece 100. The specifications, the number, or the intervals of the heaters 33 may be appropriately determined by performing a simulation or an experiment.

The heater 33 is, for example, a sheath heater, a far-infrared heater, a far-infrared lamp, a ceramic heater, or a cartridge heater. Further, various heaters may be covered with a quartz cover.

Further, the heater 33 may be a rod-shaped heater extending in one direction. In the specification, the term “rod-shaped heater” includes various heaters covered with a quartz cover. Further, the exterior shape of the “rod-shape” is not limited, and for example, may be cylindrical or prismatic.

Further, the heater 33 is not limited to the one described above as long as it can heat the workpiece 100 in an atmosphere decompressed below atmospheric pressure. That is, the heater 33 may be any device that uses heat energy by radiation.

The cooling unit 40 supplies a cooling gas to the cassette 50 in cooperation with a cooling unit 57 (to be described later) provided in the cassette 50. As will be described later, the cooling gas supplied to the cassette 50 is supplied to the workpiece 100 supported inside the cassette 50. Further, the cooling gas supplied to the cassette 50 is also supplied to a soaking plate (upper soaking plate 52, lower soaking plate 53, side soaking plate 54, side soaking plate 55) (to be described later) of the cassette 50.

By supplying the cooling gas to the workpiece 100, the workpiece 100 in a high temperature is directly cooled. Further, by supplying the cooling gas supplied to the workpiece 100 to the soaking plate of the cassette 50, the cassette 50 is also cooled. By cooling the cassette 50, the heat of the cassette 50 may be suppressed from being transferred to the workpiece 100. Therefore, the workpiece 100 is indirectly cooled by the cassette 50.

When the cooling unit 40 is provided, the cooling time of the workpiece 100 may be shortened. Further, at the time of cooling the workpiece 100, the variations in the temperature distribution may be suppressed from occurring in the in-plane of the workpiece 100 due to the heat from the cassette 50.

The cooling unit 40 includes, for example, a joint 41, a gas source 42, and a gas controller 43. The joint 41, the gas source 42, and the gas controller 43 are connected by a pipe 44.

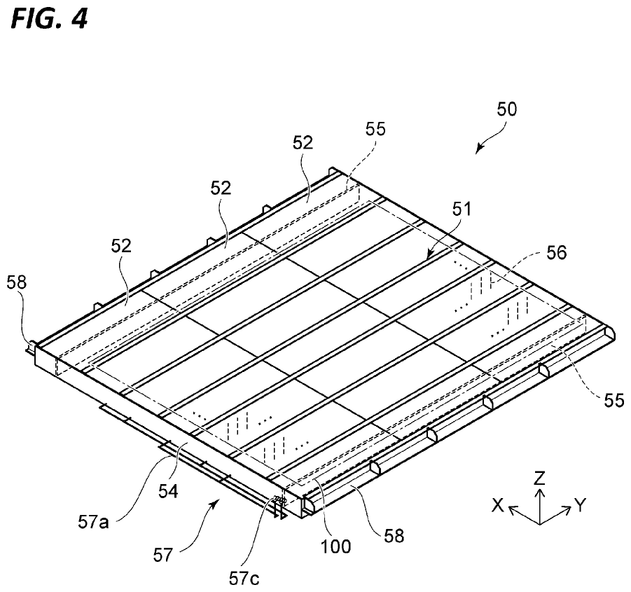

The joint 41 is, for example, attachably/detachably connected to a pipe 57a or a joint 57c of the cooling unit 57 provided in the cassette 50 (see FIG. 4). When the pipe 44 connected to the gas controller 43 is attachably/detachably connected to the joint 57c of the cooling unit 57 provided in the cassette 50, the joint 41 may be omitted.

The gas source 42 supplies the cooling gas to the cooling unit 57 of the cassette 50 via the gas controller 43. The gas source 42 may be, for example, a high-pressure gas bomb or a factory pipe.

The cooling gas is not particularly limited as long as it is a gas that hardly reacts with the heated workpiece 100. The cooling gas is, for example, nitrogen gas or rare gas. The rare gas is, for example, argon gas or helium gas. The temperature of the cooling gas may be, for example, lower than or equal to room temperature (e.g., 25° C.).

The gas controller 43 is provided between the joint 41 and the gas source 42. The gas controller 43 can control at least one of the supply of the cooling gas, the stop of the supply, and the flow velocity and the flow rate of the cooling gas.

In order to avoid complexity, the straight-type pipe 44 is illustrated in FIGS. 1 and 2. However, when a plurality of cassettes 50 is provided in the chamber 10, it goes without saying that the pipe 44 may be a pipe including a plurality of branches.

Subsequently, the cassette 50 will be described in detail. As illustrated in FIG. 1, the cassette 50 is attachably/detachably provided on the pair of receiving members 62 of the cassette rack 60 provided inside the chamber 10. In this case, the cassette 50 is attachably/detachably provided between the first heating unit 31 and the second heating unit 32.

FIG. 4 is a schematic perspective view illustrating an exterior of the cassette 50.

As illustrated in FIG. 4, the cassette 50 has a box shape, and includes a space in which the workpiece 100 is supported. The exterior shape of the cassette 50 is not particularly limited. The exterior shape of the cassette 50 may be, for example, a rectangular parallelepiped.

The cassette 50 includes, for example, a cassette frame 51, the upper soaking plate 52, the lower soaking plate 53, the side soaking plate 54, the side soaking plate 55, a workpiece support portion 56, the cooling unit 57, and a cassette support portion 58.

The cassette frame 51 forms an outer edge of the processing space in which the workpiece 100 is heated. In the embodiment, the cassette frame 51 forms an outer edge of the space surrounded by the upper soaking plate 52, the lower soaking plate 53, the side soaking plate 54, and the side soaking plate 55. The cassette frame 51 is, for example, a frame structure using an elongated plate member or a shaped steel. Alternatively, the cassette frame 51 may be a frame body formed by sheet metal processing. The exterior shape of the cassette frame 51 is not particularly limited. The cassette frame 51 forms, for example, an edge of a rectangular parallelepiped. The cassette frame 51 includes a frame-shaped member 51a, a pillar 51b, and a beam 51c.

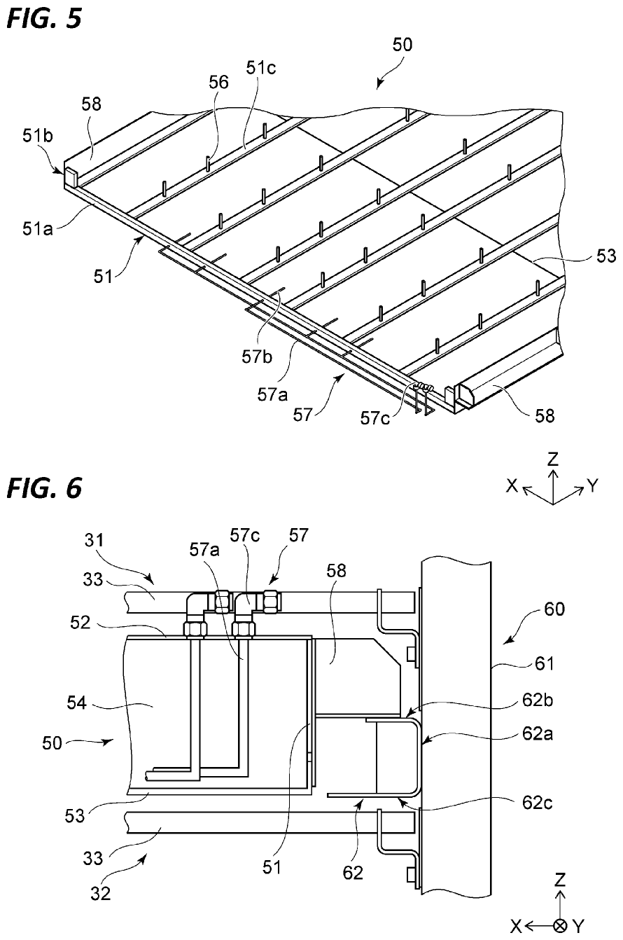

FIG. 5 is a schematic perspective view illustrating the inside of the cassette 50.

The frame-shaped member 51a has a role that constitutes an upper surface and a lower surface of the processing space described above. As a result, two frame-shaped members 51a are disposed vertically. In FIG. 5, in order to avoid complexity, the upper frame-shaped member 51a is omitted.

The frame-shaped member 51a has, for example, a rectangular frame shape. The frame-shaped member 51a is, for example, formed by combining a plurality of elongated plate members or shaped steels. Alternatively, the frame-shaped member 51a is formed by processing a single elongated plate member or shaped steel into a frame shape by sheet metal processing. The frame-shaped member 51a is made of, for example, metal such as stainless steel.

Hereinafter, an opening of the upper frame-shaped member 51a may be referred to as an “upper portion of the cassette frame 51.” Further, an opening of the lower frame-shaped member 51a may be referred to as a “lower portion of the cassette frame 51.”

The pillar 51b is a member configured to connect the two frame-shaped members 51a. Further, the pillar 51b has a role that constitutes the side surface of the processing space described above together with the frame-shaped member 51a. The pillar 51b connects the two frame-shaped members 51a, for example, at each corner of the frame-shaped member 51a. The pillar 51b connects the two frame-shaped members 51a at each corner of the frame-shaped member 51a, and thus, a gap is formed between the two frame-shaped members 51a. Hereinafter, this gap is referred to as a side portion of the cassette frame 51. The pillar 51b is made of, for example, metal such as stainless steel.

The beam 51c is formed in the frame-shaped member 51a. The beam 51c is a member configured to suppress the thermal deformation of the frame-shaped member 51a. The beam 51c is formed, for example, to connect the two sides of the frame-shaped member 51a facing to each other. In the embodiment, six beams 51c are provided. The beam 51c is made of, for example, metal such as stainless steel.

The upper soaking plate 52 has a plate shape, and is provided on the upper portion of the cassette frame 51. The upper soaking plate 52 may be attachably/detachably provided on the upper portion of the cassette frame 51. For example, the upper soaking plate 52 may be fixed to the frame-shaped member 51a and the beam 51c via a screw. Alternatively, a groove may be formed in the side surface of the frame-shaped member 51a and the beam 51c. The upper soaking plate 52 is fixed by fitting the upper soaking plate 52 into the groove in the side surface of the frame-shaped member 51a and the beam 51c. At least one upper soaking plate 52 may be provided. In the cassette 50 illustrated in FIG. 4, 21 upper soaking plates 52 are provided. The plane shape of the upper soaking plate 52 may be, for example, a rectangular shape. The number and the plane shape of the upper soaking plates 52 may be appropriately changed according to the size and the shape of the upper portion of the cassette frame 51.

The lower soaking plate 53 has a plate shape, and is provided on the lower portion of the cassette frame 51 (see FIG. 5). Similarly to the upper soaking plate 52, the lower soaking plate 53 may be attachably/detachably provided on the lower portion of the cassette frame 51. The lower soaking plate 53 faces the upper soaking plate 52. At least one lower soaking plate 53 may be provided. The number and the plane shape of the lower soaking plates 53 may be the same as, or different from the number and the plane shape of the upper soaking plates 52.

In FIGS. 4 and 5, a case where a plurality of upper soaking plates 52 and a plurality of lower soaking plates 53 are provided is illustrated, but at least one of the upper soaking plate 52 and the the lower soaking plate 53 may be a single plate-shaped member.

The side soaking plate 54 has a plate shape. In the embodiment, two side soaking plates 54 are used for one cassette 50. One side soaking plate 54 is provided on one of the side portions of the cassette frame 51 facing to each other. The workpiece 100 is loaded into the cassette 50 through the opening formed in the side portion of the cassette frame 51. Also, the workpiece 100 is unloaded from the inside of the cassette 50 through the opening formed in the side portion of the cassette frame 51. As a result, the side portion of the cassette frame 51, which is opposite to the side portion on which the side soaking plate 54 is provided, is opened.

The other side soaking plate 54 is provided adjacent to the side portion of the cassette frame 51, which is opposite to the side portion on which the one side soaking plate 54 is provided. For example, the other side soaking plate 54 may be provided in the opening/closing door 13. Alternatively, at least one of the side soaking plates 54 is provided on the side portion of the cassette frame 51 to be freely opened and closed.

A pair of side soaking plates 55 are provided inside the cassette frame 51. The pair of side soaking plates 55 face each other, and extend between a pair of side soaking plates 54. One of the pair of side soaking plates 55 is provided in the vicinity of one side portion of the cassette frame 51 on which the cassette support portion 58 is provided. The other of the pair of side soaking plates 55 is provided in the vicinity of the other side portion of the cassette frame 51 on which the cassette support portion 58 is provided.

The space surrounded by the upper soaking plate 52, the lower soaking plate 53, the side soaking plates 54, and the side soaking plates 55 serves as the processing space in which the workpiece 100 is heated. The processing space inside the cassette 50 and the internal space of the chamber 10 are connected to each other via, for example, gaps between the soaking plates. As a result, when the pressure of the internal space of the chamber 10 is decompressed, the pressure of the processing space inside the cassette 50 is also decompressed.

Here, as described above, a plurality of heaters 33 having a rod shape may be provided to be arranged side by side at predetermined intervals. When the heater 33 has a rod shape, heat is radiated radially around the central axis of the heater 33. In this case, the shorter the distance between the central axis of the heater 33 and the heated portion, the higher the temperature of the heated portion. That is, when the workpiece 100 is directly heated using a plurality of heaters 33 having a rod shape, the temperature distribution in the in-plane of the heated workpiece 100 is varied.

When the temperature distribution in the in-plane of the workpiece 100 is varied, the quality of the organic film formed thereon may be deteriorated. For example, in the portion where the temperature becomes high, bubbles may occur or the composition of the organic film may be changed.

When the upper soaking plate 52 and the lower soaking plate 53 are provided, the heat radiated from a plurality of heaters 33 are incident on the upper soaking plate 52 and the lower soaking plate 53. The heat incident on the upper soaking plate 52 and the lower soaking plate 53 is propagated through the inside of the upper soaking plate 52 and the lower soaking plate 53 in the plane direction, and is radiated toward the workpiece 100. As a result, the variations in the temperature distribution may be suppressed from occurring in the in-plane of the workpiece 100. Eventually, the quality of the formed organic film may be improved.

The material of the upper soaking plate 52 and the lower soaking plate 53 may be a material having a high heat conductivity. The material may be, for example, aluminum, copper, and stainless steel. When the material that is easily oxidized such as aluminum or copper is used, a layer containing a material that is not easily oxidized may be provided on the surface.

A part of the heat radiated from the upper soaking plate 52 and the lower soaking plate 53 is directed to the side of the processing space. As a result, the side soaking plates 54 and 55 are provided in the cassette 50. The heat incident on the side soaking plates 54 and 55 is propagated through the side soaking plates 54 and 55 in the plane direction, and a part thereof is radiated toward the workpiece 100. As a result, the heating efficiency of the workpiece 100 may be improved.

The material of the side soaking plates 54 and 55 may be the same as the material of the upper soaking plate 52 and the lower soaking plate 53 described above.

As illustrated in FIGS. 4 to 5, a plurality of workpiece support portions 56 is provided inside the cassette 50. The plurality of workpiece support portions 56 support the back surface of the workpiece 100 in the processing space in which the workpiece 100 is heated. The plurality of workpiece support portions 56 support the workpiece 100 so that the workpiece 100 faces the upper soaking plate 52 and the lower soaking plate 53.

The plurality of workpiece support portions 56 may have a rod shape.

The shape of one end portion (end portion of the workpiece 100 side) of the plurality of workpiece support portions 56 may be hemispherical. When the shape of one end portion of the plurality of workpiece support portion 56 is hemispherical, the back surface of the workpiece 100 may be suppressed from being damaged. Further, the contact area between the back surface of the workpiece 100 and the plurality of workpiece support portions 56 may be reduced. As a result, the heat transferred from the workpiece 100 to the plurality of workpiece support portions 56 may be reduced.

The other end portion (end portion opposite to the workpiece 100 side) of the plurality of workpiece support portions 56 may be, for example, fixed to the beam 51c of the cassette frame 51, to which the lower soaking plate 53 is attached.

The plurality of workpiece support portions 56 may be made of, for example, stainless steel.

The number, the placing, or the intervals of the plurality of workpiece support portions 56 may be appropriately changed according to the size or the rigidity (deflection) of the workpiece 100.

The cooling unit 57 has a role that supplies the cooling gas supplied from the cooling unit 40 described above to the workpiece 100 inside the cassette 50. The cooling unit 57 may be provided, for example, on the side surface of the cassette frame 51, to which the side soaking plate 54 is attached.

As illustrated in FIG. 5, the cooling unit 57 includes, for example, the pipe 57a, a nozzle 57b, and the joint 57c.

The pipe 57a is a pipe configured to supply the cooling gas supplied from the cooling unit 40 described above to the nozzle 57b. The end portion of the pipe 57a connected to the cooling unit 40 is, for example, formed outside the cassette 50 (cassette frame 51). The end portion of the pipe 57a opposite to the end portion connected to the cooling unit 40 may be attached, for example, to the side surface of the cassette frame 51, to which the side soaking plate 54 is attached. In the embodiment, as illustrated in FIG. 5, the end portion of the pipe 57a opposite to the end portion connected to the cooling unit 40 may be attached to one side of the lower frame-shaped member 51, to which the side soaking plate 54 is attached. Hereinafter, the end portion of the pipe 57a opposite to the end portion connected to the cooling unit 40 may be referred to as a “tip end of the pipe 57a.”

At least one pipe 57a may be provided. Further, the tip end of the pipe 57a may be branched to have a plurality of tip ends. In the embodiment, the pipe 57a having one tip end and the pipe 57a having four tip ends are attached to the above-described side of the lower frame-shaped member 51a.

The nozzle 57b is provided inside the cassette 50 (cassette frame 51). The nozzle 57b is provided in the processing space described above. For example, the nozzle 57b supplies the cooling gas to the back surface of the workpiece 100 supported in the internal space of the cassette 50.

At least one nozzle 57b may be provided. In this case, when a plurality of nozzles 57b is provided, it is facilitated to uniformly cool the workpiece 100 and shorten the cooling time. For example, as illustrated in FIG. 5, the nozzle 57b may be attached to the tip end of the pipe 57a.

The number of the tip ends of the pipe 57a and the number of the nozzles 57b are not necessarily to be coincided. For example, when the number of the tip ends of the pipe 57a is larger than the number of the nozzles 57b, a cap may be provided on the tip end of the pipe 57a to which the nozzle 57b is not attached.

When viewed from the direction perpendicular to the surface of the workpiece 100, a discharge port of the nozzle 57b may be provided at a position that is not overlapping the workpiece 100.

The discharge port of the nozzle 57b may be bent to be inclined with respect to the back surface of the workpiece 100. In this case, the position of the discharge port of the nozzle 57b and the inclination angle are set such that the cooling gas discharged from the nozzle 57b is supplied to the vicinity of the end portion of the back surface of the workpiece 100. The angle (inclination angle) between the discharge port of the nozzle 57b and the back surface of the workpiece 100 may be, for example, larger than 0° and 30° or less.

Here, the flow velocity of the cooling gas on the back surface of the workpiece 100 becomes slower as the distance from the nozzle 57b increases. In the region where the flow velocity of the cooling gas is slow, the temperature boundary layer becomes thicker, and thus, the heat transfer coefficient is lowered. As a result, the lowering of the temperature in the region where the flow velocity of the cooling gas is slow may be insufficient. When there is a region where the lowering of the temperature is insufficient, variations may occur in the temperature distribution in the in-plane of the workpiece 100, or the cooling time required to reach a uniform temperature may be increased.

In the cassette 50 according to the embodiment, the nozzle 57b is disposed as described above. As a result, the cooling gas discharged from the nozzle 57b may flow along the back surface of the workpiece 100 from one end portion to the other end portion in the Y-direction. When the cooling gas flows on the back surface of the workpiece 100 in one direction, it is possible to suppress the occurrence of regions where the flow velocity decreases or stagnation occurs.

As a result, the region where the flow velocity of the cooling gas is fast may be increased. In the region where the flow velocity of the cooling gas is fast, the temperature boundary layer becomes thinner. As a result, the heat transfer coefficient may be increased. When the heat transfer coefficient can be increased, the variations in the temperature distribution may be suppressed from occurring in the in-plane of the workpiece 100, or the cooling time may be shorten.

The joint 57c plays a role of connecting the above-described cooling unit 40 and the pipe 57a of the cooling unit 57. The joint 57c is connected to the nozzle 57b through the pipe 57a. The joint 57c is, for example, attachably/detachably connected to the joint 41 of the cooling unit 40 described above or the pipe 44. When the pipe 57a connected to the nozzle 57b is attachably/detachably connected to the joint 41 provided in the cooling unit 40, the joint 57c may be omitted.

The cassette support portion 58 is provided on the side surface of the cassette frame 51 that intersects with the side surface on which the side soaking plate 54 is provided. A pair of cassette support portions 58 are provided. The cassette support portion 58 protrudes toward outside from the side surface of the cassette frame 51, and extends in a direction orthogonal to the side surface on which the side soaking plate 54 is provided.

The cassette support portion 58 is provided on each of the pair of side surfaces of the cassette 50 facing each other. The cassette support portion 58 is supported by the receiving member 62 of the cassette rack 60 (to be described later). As a result, the cassette 50 may be placed inside the chamber 10. Further, the cassette support portion 58 plays a role of being supported by a loading/unloading jig 200 (to be described later), when the cassette 50 is loaded into the chamber 10 or unloaded from the inside of the chamber 10. Hereinafter, loading the cassette 50 into the chamber 10 is referred to as “loading the cassette 50.” Further, unloading the cassette 50 out from the inside of the chamber 10 is referred to as “unloading the cassette 50.”

Subsequently, the cassette rack 60 will be described. As illustrated in FIGS. 1 to 3, the cassette rack 60 is provided inside the chamber 10. The cassette rack 60 has a role that fixes the heater 33 and the cassette 50 at a predetermined position in the chamber 10. The cassette rack 60 includes a frame 61, the receiving member 62, and a reflecting plate 63.

The frame 61 has, for example, a frame structure constituted by using an elongated member. The exterior shape of the frame 61 is not particularly limited. The exterior shape of the frame 61 may be, for example, a rectangular parallelepiped or a cylinder.

The frame 61 may be one elongated member obtained by connecting a plurality of elongated members. In the embodiment, as illustrated in FIG. 1, the elongated member that constitutes the frame 61 and is parallel to the Z-direction is formed by connecting two elongated members.

At least one pair of receiving members 62 are provided inside the frame 61. The pair of receiving members 62 has a role that supports the cassette 50 in the chamber 10. Further, the receiving member 62 also has a role that supports the loading/unloading jig 200 (to be described later), when loading the cassette 50 or unloading the cassette 50. In the Z-direction, the pair of receiving members 62 are provided between the first heating unit 31 and the second heating unit 32. One cassette 50 is placed on the pair of receiving members 62. As a result, the pair of receiving members 62 are provided for each cassette 50. For example, when fourteen cassettes 50 will be accommodated inside the frame 61, fourteen sets of the pair of receiving members 62 are provided inside the frame 61.

Each of the pair of receiving members 62 may be provided, for example, on the inner walls of the frame 61 having a frame structure, facing each other in the X-direction. The pair of receiving members 62 extend in the Y-direction. When a plurality of sets of the pair of receiving members 62 is provided, the pair of receiving members 62 may be provided to be arranged in the Z-direction.

FIG. 6 is a schematic view illustrating a portion where the receiving member 62 of the frame 61 of the cassette rack 60 is provided.

As illustrated in FIG. 6, the receiving member 62 may be, for example, an elongated member formed by sheet metal processing. The receiving member 62 includes, for example, two end portions in the short length direction and a side portion that connects the two end portions. That is, the receiving member 62 includes a side portion 62a, an upper end portion 62b, and a lower end portion 62c.

The side portion 62a of the receiving member 62 plays a role of connecting the upper end portion 62b and the lower end portion 62c. The receiving member 62 has, for example, a U shape in a cross section parallel to the short length direction. Therefore, the side portion 62a of the receiving member 62 corresponds to the bottom portion of the U shape. That is, the receiving member 62 has a cross-sectional shape obtained by inclining a U shape by 90°. The side portion 62a of the receiving member 62 is attached to the inner wall of the frame 61, for example, using a fastening member such as a screw.

The upper end portion 62b (corresponding to an example of a first end portion) of the receiving member 62 is formed on the upper end portion of the side portion 62a, and is substantially orthogonal to the side portion 62a. The cassette support portion 58 of the cassette 50 is placed on the upper surface of the upper end portion 62b of the receiving member 62. As a result, the cassette 50 is attachably/detachably provided inside the frame 61 by the pair of receiving members 62. Eventually, the cassette 50 is attachably/detachably provided inside the chamber 10. In the embodiment, in order to increase the strength of the upper end portion 62b of the receiving member 62, a rib is provided between the upper end portion 62b and the lower end portion 62c. As a result, the upper end portion 62b of the receiving member 62 may be suppressed from being deformed due to the weight of the cassette 50.

As described above, the pair of receiving members 62 are provided between the first heating unit 31 and the second heating unit 32. As a result, when the cassette support portion 58 of the cassette 50 is placed on the pair of receiving members 62, the cassette 50 is supported between the first heating unit 31 and the second heating unit 32.

The lower end portion 62c (corresponding to an example of a second end portion) of the receiving member 62 is formed on the lower end portion of the side portion 62a, and is substantially orthogonal to the side portion 62a. The lower end portion 62c faces the upper end portion 62b. Hereinafter, the end portion of the lower end portion 62c opposite to the side portion 62a side is referred to as a “tip end of the lower end portion 62c.” Further, the end portion of the upper end portion 62b opposite to the side portion 62a side is referred to as a “tip end of the upper end portion 62b.” The tip end of the lower end portion 62c is positioned inside the frame 61 from the tip end of the upper end portion 62b.

That is, the receiving member 62 includes the upper end portion 62b that is provided on the first heating unit 31 side and supports the cassette support portion 58 of the cassette 50, and the lower end portion 62c that is provided on the second heating unit 32 side and faces the upper end portion 62b.

When viewed in a direction toward the lower end portion 62c from the upper end portion 62b, the tip end of the lower end portion 62c is positioned on the side surface side of the cassette 50 on which the cassette support portion 58 is provided from the tip end of the upper end portion 62b.

In this case, as illustrated in FIG. 6, a gap is provided between the tip end of the upper end portion 62b and the side surface of the cassette 50 on which the cassette support portion 58 is provided. As a result, a part of the cassette support portion 58 of the cassette 50 is exposed above the lower end portion 62c.

As will be described later, the loading/unloading jig 200 is attachably/detachably provided on the surface of the lower end portion 62c on the upper end portion 62b side. That is, the space defined by the lower end portion 62c, the upper end portion 62b, and the side portion 62a serves as a space in which the loading/unloading jig 200 is attachably/detachably provided. When the loading/unloading jig 200 is provided on the lower end portion 62c, when a part of the cassette support portion 58 of the cassette 50 is exposed above the lower end portion 62c, the cassette support portion 58 may be moved upward and downward by the loading/unloading jig 200. That is, by the loading/unloading jig 200, the cassette 50 may be separated upward from the upper end portion 62b, or the cassette 50 may be placed on the upper end portion 62b.

The reflecting plate 63 has a function of reflecting the heat incident from the heater 33 side to the processing space in the cassette 50. The reflecting plate 63 has a plate shape, and is provided on the outer periphery of the frame 61. For example, when the exterior shape of the frame 61 is a rectangular parallelepiped, the reflecting plate 63 is provided on each surface of the rectangular parallelepiped. In order to avoid complexity, the reflecting plate 63 is not illustrated in FIGS. 1 and 2. Further, in FIG. 3, the reflecting plate 63 attached to the side surface of the frame 61 on which the receiving member 62 is attached is illustrated.

Here, when the reflecting plate 63 is provided on the surface of the frame 61 facing the opening/closing door 13, it is difficult to load the workpiece 100 into the cassette 50 or unload the workpiece 100 from the cassette 50. As a result, the reflecting plate 63 on the opening/closing door 13 side may be provided between the opening/closing door 13 and the side soaking plate 54.

Further, when the reflecting plate 63 is provided on the surface of the frame 61 facing the lid 15, when the cassette 50 is unloaded, it is necessary to detach the reflecting plate 63 from the frame 61. As a result, the reflecting plate 63 on the lid 15 side may be provided on the lid 15. Alternatively, the reflecting plate 63 may have a structure in which the same number of the plates as the number of the cassettes 50 are arranged. In this case, when loading the cassette 50 or unloading the cassette 50, the corresponding reflecting plate 63 is detached. As a result, loading the cassette 50 or unloading the cassette 50 may be performed by detaching the minimum number of the reflecting plates 63. Therefore, the operation of detaching the reflecting plate 63 is facilitated.

The reflecting plate 63 reflects the heat incident from the heater 33 side to the processing space in the cassette 50, and thus, the heat storage property of the processing space in the cassette 50 may be improved.

Here, when the solution of the workpiece 100 is heated, vapor containing a sublimated product is generated. The vapor containing the sublimated product is likely to be attached to an object having a temperature lower than the temperature of the workpiece 100. When the workpiece 100 is heated, the upper soaking plate 52, the lower soaking plate 53, and the side soaking plates 54 and 55 are also heated. As a result, the sublimated product is suppressed from being attached to the upper soaking plate 52, the lower soaking plate 54, and the side soaking plates 54 and 55. However, for example, the number of works 100 that are processed increases, the sublimated product may be attached to the component of the cassette 50.

As described above, the cassette 50 is attachably/detachably provided inside the chamber 10. As a result, when the sublimated product is attached to the component of the cassette 50, the cassette 50 may be easily detached from the chamber 10. Therefore, the sublimated product attached to the cassette 50 may be removed from the outside of the chamber 10.

Further, extra cassettes 50 may be manufactured in advance. As a result, for example, while cleaning the cassette 50 to which the sublimated product is attached, the heat treatment of the workpiece 100 may be performed using another cassette 50.

As described above, the heat treatment apparatus 1 according to the embodiment includes the cassette 50 attachably/detachably provided inside the chamber 10. As a result, the maintenance may be facilitated.

Here, when loading the cassette 50 or unloading the cassette 50, when friction occurs between the receiving member 62 and the cassette support portion 58 of the cassette 50, particles may be generated. When the generated particles are attached to the workpiece 100, the quality of the formed organic film may be deteriorated.

In this case, for example, it is conceivable to provide the receiving member 62 with a rotating member such as a roller. When the cassette support portion 58 of the cassette 50 is placed on the rotating member, the friction may be suppressed from occurring between the rotating member and the cassette support portion 58. As a result, the occurrence of the particles may be suppressed.

However, when the receiving member 62 is provided with the rotating member, when the workpiece 100 is heated, the rotating member is also heated. For example, the rotating member may be heated to a high temperature. When the rotating member reaches a high temperature, for example, a component of the rotating member such as a rotating shaft may be distorted, which makes it difficult to rotate or makes it impossible to rotate. As a result, friction between the rotating member and the cassette support portion 58 or friction between the components is generated. As a result, particles may be generated.

Therefore, in the heat treatment apparatus 1 according to the embodiment, the loading/unloading jig 200 is attachably/detachably provided on the receiving member 62. The loading/unloading jig 200 may be provided on the receiving member 62 when the cassette 50 is attached/detached from the receiving member 62 of the cassette rack 60. As a result, the loading/unloading jig 200 is not heated during the heat treatment. Therefore, as in the case where the receiving member 62 is provided with the rotating member, particles are not generated due to the heating of the loading/unloading jig 200.

Subsequently, the loading/unloading jig 200 and a method for loading/unloading the cassette 50 using the loading/unloading jig 200 will be described.

The loading/unloading jig 200 is a jig used when loading the cassette 50 or unloading the cassette 50.

A pair of loading/unloading jigs 200 are used for one cassette 50 to be loaded or unloaded. At least one pair of loading/unloading jigs 200 may be provided for, for example, at least one heat treatment apparatus 1. For example, at least one pair of loading/unloading jigs 200 may be provided for one heat treatment apparatus 1. For example, at least one pair of loading/unloading jigs 200 may be provided for a plurality of heat treatment apparatuses 1.

The loading/unloading jig 200 is attachably/detachably provided between the upper end portion 62b and the lower end portion 62c of the receiving member 62. Further, the loading/unloading jig 200 may be moved to a raised position and a lowered position. As a result, the loading/unloading jig 200 moves the cassette 50 upward and downward. Hereinafter, the raised position of the loading/unloading jig 200 is referred to as a “raised end.” Further, the lowered position of the loading/unloading jig 200 is referred to as a “lowered end.”

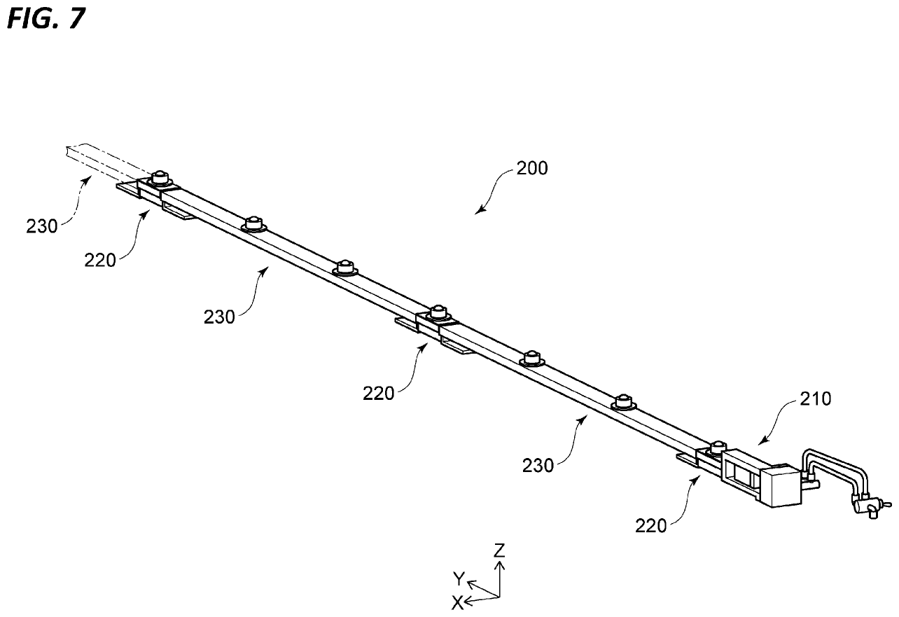

FIG. 7 is a schematic perspective view illustrating the loading/unloading jig 200 used to load or unload the cassette 50 to or from the chamber 10.

As illustrated in FIG. 7, the loading/unloading jig 200 includes, for example, a driving unit 210, a lifting unit 220, and a connecting unit 230.

The driving unit 210 plays a role as a power source for moving the loading/unloading jig 200 to the raised end or the lowered end. At least one driving unit 210 may be provided.

The lifting unit 220 plays a role of moving the loading/unloading jig 200 upward or downward. Two or more lifting units 220 may be provided. One lifting unit 220 is provided to be connectable to and separable from the driving unit 210. Further, the lifting units 220 are provided to be connectable to and separable from each other. Further, the lifting units 220 may be connected to each other via the connecting unit 230. Therefore, for example, other lifting units 220 are provided to be arranged at predetermined intervals in the Y-direction with the lifting unit 220 provided in the driving unit 210.

The connecting unit 230 is provided between the lifting unit 220 and the lifting unit 220 to be connectable and separable. One or more connecting units 230 may be provided. The number of the connecting units 230 is less than the number of the lifting units 220 by one. When a plurality of connecting units 230 is provided, the length of the plurality of connecting units 230 in the Y-direction may be equal, or may be different from each other.

The loading/unloading jig 200 according to the embodiment may change the number of the lifting units 220 and the connecting units 230 to be combined. Further, the loading/unloading jig 200 according to the embodiment may change the length of the connecting unit 230. In this manner, the length of the loading/unloading jig 200 in the Y-direction may be changed. As a result, it is possible to deal with the cassette 50 having a different length in the Y-direction.

Here, when the length of the cassette 50 in the Y-direction is long, the length of the loading/unloading jig 200 is lengthened. When the length of the loading/unloading jig 200 is lengthened, it becomes difficult to handle or store the loading/unloading jig 200. However, as will be described later, the driving unit 210, the lifting unit 220, and the connecting unit 230 are configured to be connectable to and separable from each other. As a result, when using the loading/unloading jig 200, the lifting unit 220 and the connecting unit 230 may be connected while being placed inside the receiving member 62. Then, finally, the driving unit 210 may be connected to the lifting unit 220. Further, when detaching the loading/unloading jig 200, the driving unit 210, the lifting unit 220, and the connecting unit 230 may be separated in the reversed procedure. As a result, even when the long loading/unloading jig 200 is necessary, the handling or the storage is facilitated.

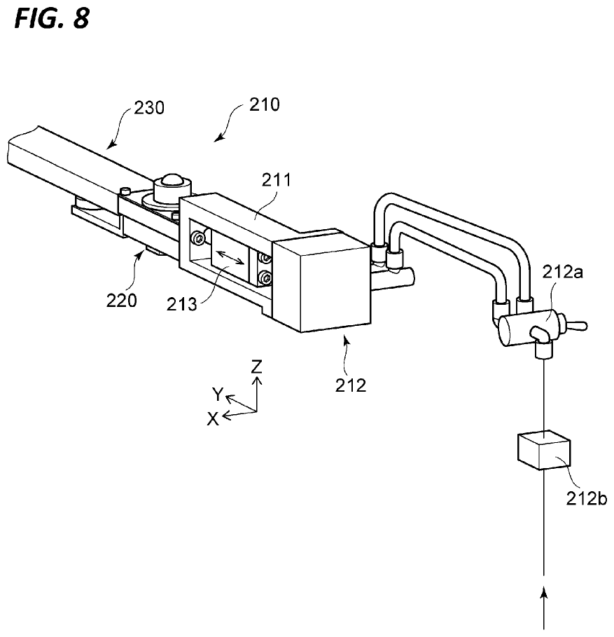

FIG. 8 is a schematic perspective view illustrating the driving unit 210 of the loading/unloading jig 200.

As illustrated in FIG. 8, the driving unit 210 includes, for example, a block 211, a driver 212, and a joint 213.

The block 211 has, for example, a tubular shape. The block 211 has a space in which the joint 213 is accommodated. The driver 212 is provided at one end portion of the block 211 in the Y-direction, and the lifting unit 220 is provided at the other end portion.

The driver 212 moves the joint 213 in the Y-direction. The driver 212 is not particularly limited as long as it is a straight driving device. The driver 212 may be, for example, an air cylinder, a hydraulic cylinder, or a solenoid, and may include a mechanism such as a motor, a ball screw, or a rack-pinion. Here, the driver 212 illustrated in FIG. 8 is an air cylinder. When the driver 212 is the air cylinder, the configuration of the driving unit 210 may be simplified. Further, when the driver 212 is the air cylinder, the force that lifts the cassette 50 may be easily adjusted.

When the driver 212 is the air cylinder, the driver 212 includes a rod 212c. Further, for example, a switching valve 212a and a regulator 212b may be provided in the driver 212.

The switching valve 212a is connected to two ports of the driver 212 via a pipe. The switching valve 212a may be, for example, a four-way valve. The position of the rod 212c in the Y-direction may be changed by the air pressure of an air source by manipulating the switching valve 212a by an operator. As a result, the position of the joint 213 in the Y-direction, and moreover, the lifted position of the loading/unloading jig 200 (to be described later) will be changed. In this case, one switching valve 212a may be provided for a pair of loading/unloading jigs 200. In this manner, the lifted portions of the pair of loading/unloading jigs 200 may be changed at the same time by manipulating one switching valve 212a by the operator.

Further, a case where the switching valve 212a is a manual valve is described, for example, the switching valve 212a may be an electromagnetic valve operated by a manual switch or the controller 70. However, when the switching valve 212a is a manual valve, the configuration may be simplified or the installation operation may be facilitated.

The regulator 212b is connected between the switching valve 212a and the air source via a pipe. The air source is, for example, a plant pipe that supplies air having a predetermined pressure. When the pressure of the air supplied to the driver 212 is controlled by the regulator 212b, the driver 212 may adjust the force that presses a shaft 222 (to be described later) of the lifting unit 220. Eventually, the force of the loading/unloading jig 200 that lifts the cassette 50 may be adjusted. The regulator 212b may be omitted. For example, the regulator 212b may be omitted in a case where the regulator 212b is provided in the air source or it is not necessary to adjust the pressure of the air supplied from the air source.

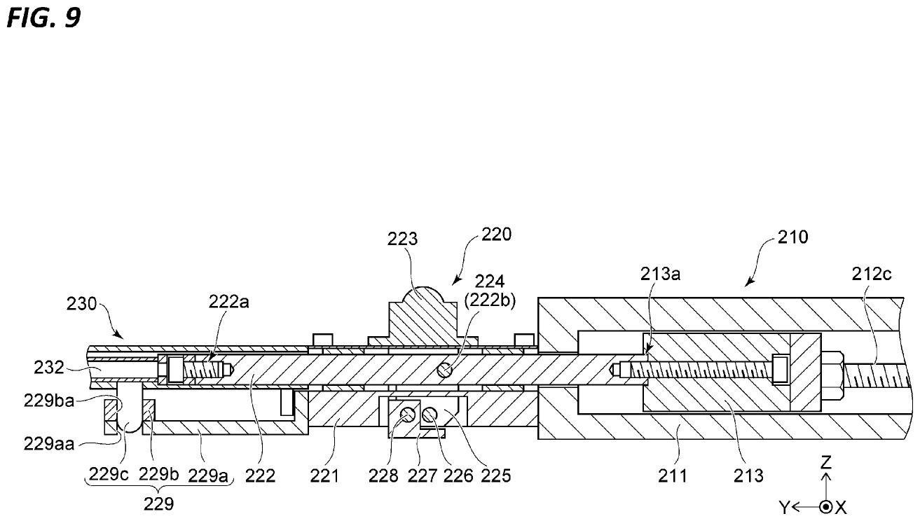

The joint 213 plays a role of transmitting the power of the driver 212 to the lifting unit 220. The joint 213 connects the rod 212c of the driver 212 and the shaft 222 (to be described later) of the lifting unit 220 with each other (see FIG. 9).

FIG. 9 is a schematic perspective view illustrating the lifting unit 220 connected to the driving unit 210 of the loading/unloading jig 200.

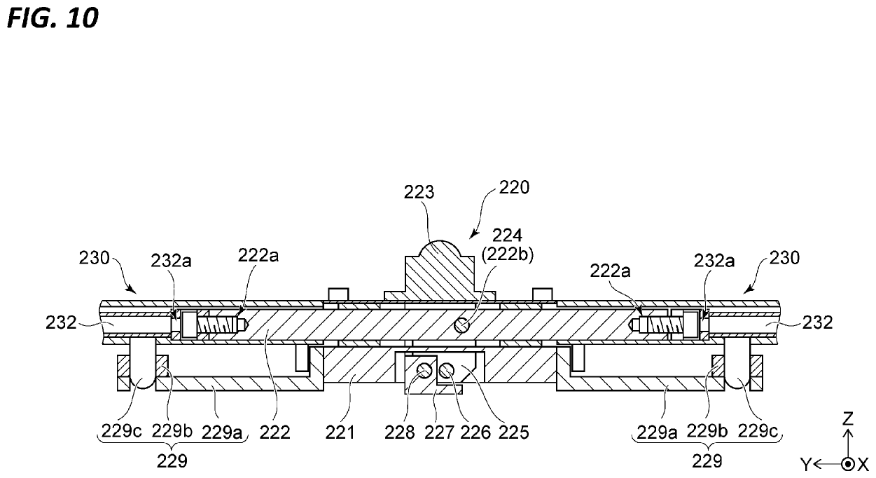

FIG. 10 is a schematic cross-sectional view illustrating the lifting unit 220 connected between the connecting unit 230 and the connecting unit 230.

The lifting unit 220 moves the loading/unloading jig 200, and moreover, a plurality of rollers 223 upward and downward.

As illustrated in FIGS. 9 and 10, the lifting unit 220 includes, for example, a block 221, the shaft 222, the roller 223, a pin 224, a link 225, a pin 226, a foot 227, a pin 228, and a transmitting unit 229.

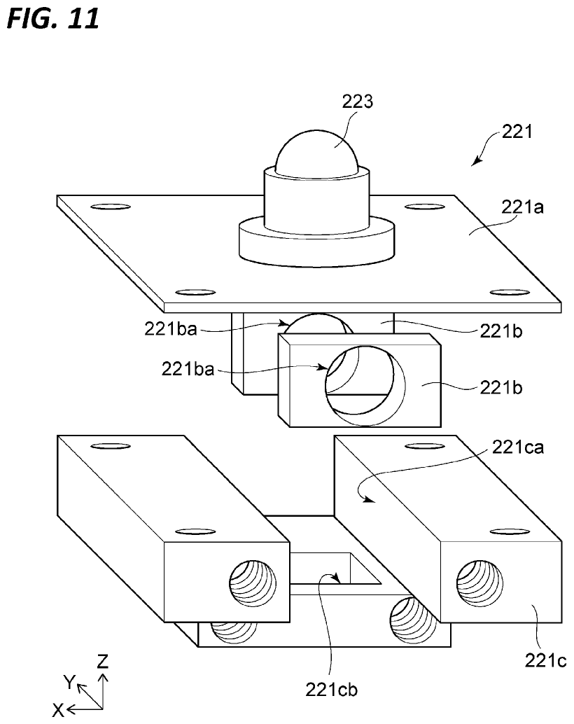

FIG. 11 is a schematic exploded view of the block 221 in FIG. 10 viewed in the Y-direction. As illustrated in FIG. 11, for example, the block 221 includes an upper plate 221a, a bearing 221b, and a base 221c.

The roller 223 is provided on an upper surface of the upper plate 221a.

The bearing 221b has a role that supports the shaft when the shaft 222 reciprocates. A pair of bearings 221b are provided on a lower surface of the upper plate 221a. The pair of bearings 221b are provided to be arranged in the Y-direction to face each other. A hole 221ba through which the shaft 222 is inserted is provided in the bearing 221b to penetrate in the thickness direction.

The base 221c is provided on the lower surface of the upper plate 221a. The base 221c includes a groove 221ca in which the pair of bearings 221b are provided. The groove 221ca is opened to the side surface of the base 221c in the Y-direction. A hole 221cb in which the link 225 and the foot 227 are provided is provided in a bottom surface of the groove 221ca. On the side surface of the base 221c in the Y-direction, a screw hole to which the transmitting unit 229 or a cover 231 (to be described later) provided in the connecting unit 230 is attached may be provided.

As illustrated in FIGS. 9 to 10, a recess portion 222a is provided at the end portion of the shaft 222. A fitting portion 232a of a shaft 232 provided in the connecting unit 230 is fitted into the recess portion 222a. The end portion of the shaft 222 is fitted into a recess portion 213a of the joint 213 provided in the driving unit 210 (see FIG. 9). Further, the shaft 222 is provided with a hole 222b that penetrates in a direction orthogonal to the axial direction. The pin 224 is inserted through the hole 222b. Further, the link 225 is connected to the shaft 222 via the pin 224.

The roller 223 plays a role of facilitating loading or unloading. The roller 223 is in contact with the cassette support portion 58 of the cassette 50. The roller 223 may be, for example, a so-called free ball-bearing.

The pin 226 is inserted through the inside of the hole 221cb provided in the base 221c of the block 221 in the X-direction. Further, the pin 226 penetrates through the link 225.

The rink 225 is configured to be swingable around the pin 226. Further, the pin 224 is inserted through the link 225. As a result, the force of the driver 212 of the driving unit 210 that moves the shaft 222 is transmitted to the link 225 via the pin 224.

The foot 227 plays a role of supporting the loading/unloading jig 200 when the loading/unloading jig 200 is raised. The foot 227 is provided at a position of the link 225 that is moved upward and downward in conjunction with the reciprocating movement of the shaft 222. The foot 227 is provided in the link 225 via pin 228 to be swingable.

The transmitting unit 229 plays a role of facilitating the reciprocating movement of the loading/unloading jig 200, when attaching/detaching the loading/unloading jig 200 to/from the receiving member 62. At least one transmitting unit 229 may be provided for the lifting unit 220.

The transmitting unit 229 includes, for example, a bracket 229a, a roller 229c, and a fixing member 229b.

The bracket 229a is provided on the side surface of the block 221 in the Y-direction. The bracket 229a is provided in the vicinity of the lower end of the side surface of the block 221. The bracket 229a has, for example, an L shape having a short side and a long side. The bracket 229a has a width the same as that of the block 221. The short side of the bracket 229a is provided on the side surface of the block 221. Two screw holes 229a a into which the rollers 229c are screwed are provided at the tip end of the long side of the block 221.

The roller 229c is provided to be rotatable around the screw hole 229aa of the bracket 229a. The roller 229c is, for example, a cylinder. A rotatable roller is provided at one end of the roller 229c. A screw groove is formed at the outer end of the roller 229c. A side surface of the roller 229c is formed as a male screw. The side surface of the roller 229c is screwed into the screw hole 229aa of the bracket 229a in a state where one end at which the roller is provided faces downward. The roller 229c is, for example, a ball plunger. Hereinafter, one end of the roller 229c may be referred to as a “lower end of the roller 229c.” Further, the other end of the roller 229c may be referred to as an “upper end of the roller 229c.”

When the lifting unit 220 is at the lowered end (when the loading/unloading jig 200 is attached to/detached from the receiving member 62), the lower end of the roller 229c is positioned below the lower end of the foot 227 (see FIG. 14). Therefore, the lower end of the roller 229c is positioned below the lower surface of the bracket 229a.

The fixing member 229b has a role that supports the bracket 229a and the roller 229c. A screw hole 229ba is provided at the center of the fixing member 229b. The male screw provided on the side surface of the roller 229c is screwed into the screw hole 229ba of the fixing member 229b. The fixing member 229b is inserted through the roller 229c from the upper end side of the roller 229c until it comes into contact with the upper surface of the bracket 229a. The fixing member 229b is brought into contact with the bracket 229a. Therefore, the roller 229c may be suppressed from being rotated in the screw hole 229aa of the bracket 229a. As a result, the position of the roller 229c may be fixed. The fixing member 229b is, for example, a nut.

As described above, the loading/unloading jig 200 is attachably/detachably provided on the lower end portion 62c of the receiving member 62. In this case, when friction occurs between the loading/unloading jig 200 and the lower end portion 62c of the receiving member 62, particles may occur.

The transmitting unit 229 including the roller 229c is provided in the loading/unloading jig 200. As a result, when the loading/unloading jig 200 is attached to/detached from the receiving member 62, the roller 229c may be brought into contact with the lower end portion 62c of the receiving member 62. Therefore, the occurrence of particles may be suppressed when attaching/detaching the loading/unloading jig 200.

In the above, the lifting unit 220 including a link mechanism has been described. However, the mechanism of the lifting unit 220 is not limited thereto. For example, a lifting unit including an air cylinder that directly lifts the block 221 may be used. However, when using the lifting unit 220 including the link mechanism, the lifting operations of a plurality of lifting units 220 may be mechanically synchronized. As a result, for example, it is facilitated to move the cassette 50 upward and downward in a state of being parallel with the receiving member 62.

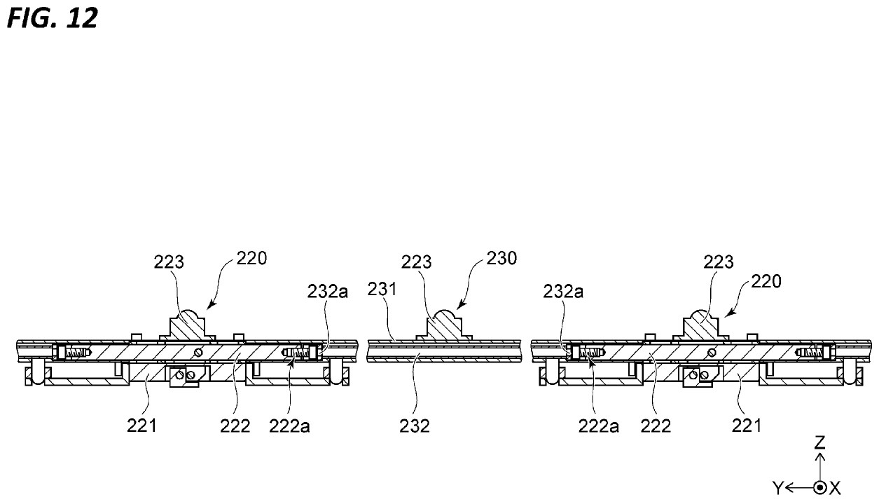

FIG. 12 is a schematic cross-sectional view illustrating the connecting unit 230 connected between the lifting unit 220 and the lifting unit 220.

As illustrated in FIG. 12, the connecting unit 230 includes, for example, the cover 231, the roller 223, and the shaft 232.

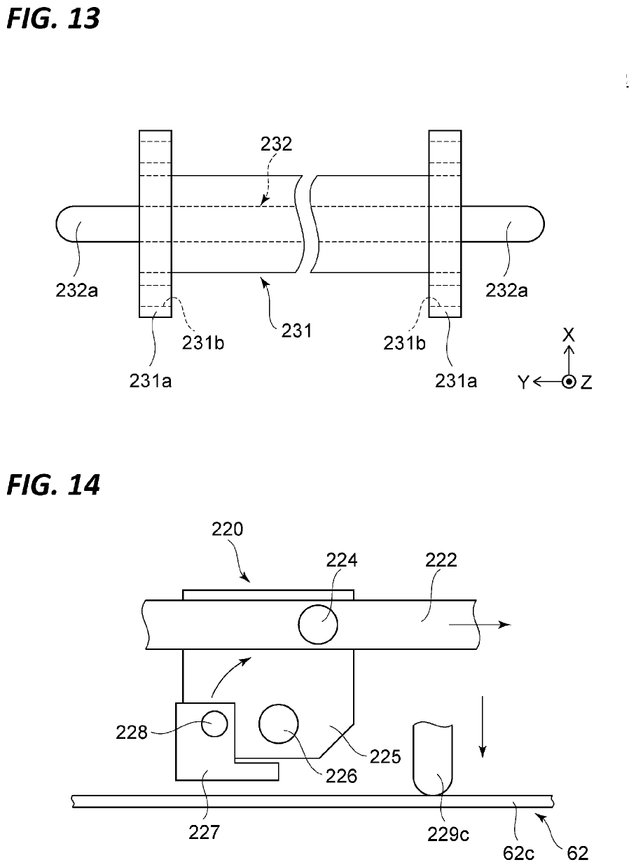

FIG. 13 is a schematic side view of the cover 231 and the shaft 232 of the connecting unit 230.

As illustrated in FIG. 13, the cover 231 has a tubular shape. The end portion of the cover 231 in the Y-direction is attachably/detachably provided in the block 221 of the lifting unit 220 (see FIG. 12). For example, a flange 231a may be provided at the end portion of the cover 231 in the Y-direction. In the flange 231a, a hole 231b corresponding to the screw hole provided on the side surface of the base 221c of the block 221 in the Y-direction is provided. As a result, the cover 231 may be attached to the block 221 using a fastening member such as a screw. In the Z-direction, the upper surface of the cover 231 is substantially at the same position as the upper surface of the block 221. The side surface of the cover 231 in the X-direction covers the side of the shaft 232.

At least one roller 223 may be provided on the upper surface of the cover 231. When the lifting unit 220 and the connecting unit 230 are connected to each other, a plurality of rollers 223 are arranged in the connection direction of the lifting unit 220 and the connecting unit 230.

The shaft 232 extends inside the cover 231 in the Y-direction.

As illustrated in FIG. 13, the fitting portion 232a may be provided at both ends of the shaft 232. The diameter dimension of the fitting portion 232a is smaller than the diameter dimension of the central portion of the shaft 232. As illustrated in FIG. 12, the fitting portion 232a is fitted into the recess portion 222a of the shaft 222 provided in the lifting unit 220. Although a case where the fitting portion 232a is fitted into the recess portion 222a has been described, for example, the fitting portion 232a may be a male screw, and the recess portion 222a may be a female screw so as to connect the shaft 232 and the shaft 222. Further, the shaft 232 and the shaft 222 may be connected to each other using a so-called one-touch clamp.

As described above, the driving unit 210, the lifting unit 220, and the connecting unit 230 are connected via the joint 213 and the shafts 222 and 232. As a result, the driving unit 210, the lifting unit 220, and the connecting unit 230 are configured to be connectable to and separable from each other.

Subsequently, the lifting operation of the loading/unloading jig 200 will be described.

FIG. 14 is a schematic view illustrating a state of the lifting unit 220 in a case where the loading/unloading jig 200 is at the lowered end.

FIG. 14 illustrates a state when the cassette 50 is transmitted onto the receiving member 62 or a state when the loading/unloading jig 200 is attached to/detached from the lower end portion 62c of the receiving member 62.

As illustrated in FIG. 14, when the shaft 222 is pulled by the driver 212 of the driving unit 210, the link 225 swings clockwise via the pin 224. At this time, since the link 225 swings around the pin 226, the foot 227 provided in the link 225 via the pin 228 moves upward from the lower end portion 62c of the receiving member 62. As a result, the entire loading/unloading jig 200 is lowered. As a result, the roller 229c of the transmitting unit 229 is brought into contact with the lower end portion 62c of the receiving member 62.

In this manner, the loading/unloading jig 200 is lowered to the lowered end. When the cassette 50 is placed on a plurality of rollers 223 provided in the loading/unloading jig 200, the loading/unloading jig 200 is lowered. As a result, the cassette 50 is transmitted onto the receiving member 62.

Further, when the loading/unloading jig 200 is attached to/detached from the lower end portion 62c of the receiving member 62, the foot 227 is not brought into contact with the lower end portion 62c of the receiving member 62. In this case, the roller 229c of the transmitting unit 229 is brought into contact with the lower end portion 62c of the receiving member 62. As a result, friction may be suppressed from occurring between the loading/unloading jig 200 and the lower end portion 62c of the receiving member 62. Therefore, the occurrence of particles may be suppressed.

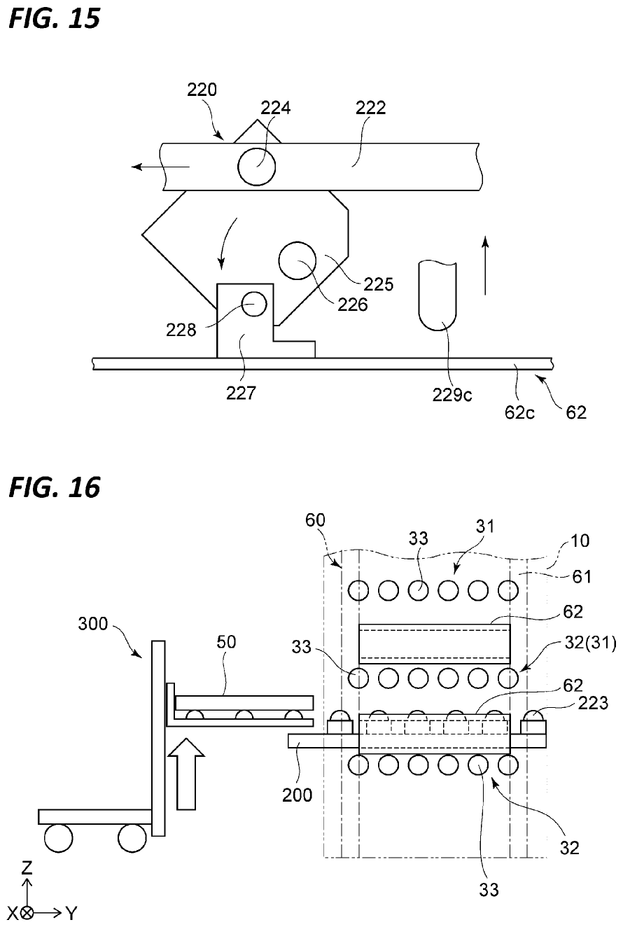

FIG. 15 is a schematic view illustrating a state of the lifting unit 220 in a case where the loading/unloading jig 200 is at the raised end.

FIG. 15 illustrates a state when the cassette 50 is lifted from the receiving member 62 or a state where the cassette 50 is moved to the position where the cassette 50 is transmitted to the receiving member 62.

As illustrated in FIG. 15, when the shaft 222 is pushed by the driver 212 of the driving unit 210, the link 225 swings anti-clockwise via the pin 224. At this time, the link 225 swings around the pin 226. As a result, the foot 227 provided in the link 225 via the pin 228 is brought into contact with the lower end portion 62c of the receiving member 62. Then, the link 225 further swings, and thus, the shaft 222 is lifted via the foot 227 and the link 225. When the shaft 222 is lifted, the entire loading/unloading jig 200 is lifted above the the receiving member 62. At this time, the roller 229c of the transmitting unit 229 is separated upward from the lower end portion 62c of the receiving member 62.

In this manner, the loading/unloading jig 200 is raised to the raised end. When the cassette 50 is placed on the receiving member 62, the cassette 50 is transmitted onto a plurality of rollers 223 provided in the loading/unloading jig 200. As a result, the cassette 50 is separated above the receiving member 62. The cassette 50 transmitted onto the plurality of rollers 223 may be easily moved in the direction (Y-direction) in which the plurality of rollers 223 are arranged. Further, friction may be suppressed from occurring between the plurality of rollers 223 and the cassette 50. Therefore, the occurrence of particles may be suppressed. The loading/unloading jig 200 maintains the state at the raised end while the cassette 50 is moved to the position where the cassette 50 is transmitted to the receiving member 62. The cassette 50 may be easily moved in the direction (Y-direction) in which the plurality of rollers 223 are arranged.

As a result, the cassette 50 may be moved to the position where the cassette 50 is transmitted to the receiving member 62.

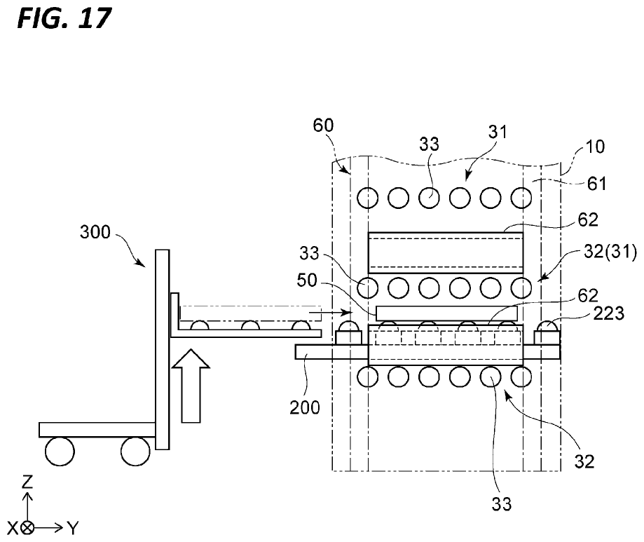

Subsequently, the method for loading/unloading the cassette 50 using the loading/unloading jig 200 will be described. FIGS. 16 and 17 are schematic views illustrating the method for loading/unloading the cassette 50. First, as illustrated in FIG. 16, the loading/unloading jig 200 is provided on each of the pair of receiving members 62 of the cassette rack 60. As described above, the loading/unloading jig 200 is provided in the space defined by the lower end portion 62c, the upper end portion 62b, and the side portion 62a of the receiving member 62. For example, the loading/unloading jig 200 is placed on the lower end portion 62c of the receiving member 62.

As described above, the driving unit 210, the lifting unit 220, and the connecting unit 230 are configured to be connectable to and separable from each other. As a result, the lifting unit 220 and the connecting unit 230 may be connected while being placed inside the receiving member 62, and finally, the driving unit 210 may be connected thereto. Therefore, even when the length of the loading/unloading jig 200 is long, it becomes easy to handle.

Subsequently, a pipe is connected to the switching valve 212a of the loading/unloading jig 200.

Continuously, the switching valve 212a is manipulated to operate the driver 212 so that the loading/unloading jig 200 is raised to the raised end. When the loading/unloading jig 200 is raised to the raised end, as illustrated in FIG. 16, the top portions of the plurality of rollers 223 protrude above the receiving member 62.

Subsequently, the cassette 50 is transported to the vicinity of the opening of the chamber 10 by using a transporting device 300 having a lifting function such as a lifter.

Continuously, the transporting device 300 moves the cassette 50 upward to adjust the position of the cassette 50 in the Z-direction. The cassette 50 is adjusted so that the position of the lower end of the cassette support portion 58 of the cassette 50 and the position of the top portion of the plurality of rollers 223 are substantially the same.

Subsequently, as illustrated in FIG. 17, the cassette 50 is pushed from the transporting device 300 to above the plurality of rollers 223.

Subsequently, the switching valve 212a is manipulated to operate the driver 212 so that the loading/unloading jig 200 is lowered to the lowered end. When the loading/unloading jig 200 is lowered to the lowered end, the plurality of rollers 223 are accommodated inside the receiving member 62. As a result, the cassette support portion 58 of the cassette 50 supported by the plurality of rollers 223 is placed on the receiving member 62.

In this manner, the cassette 50 may be loaded into the chamber 10.

When the cassette 50 is unloaded from the inside of the chamber 10, the loading/unloading jig 200 is provided on each of the pair of receiving members 62 of the cassette rack 60 in the same manner as described above. Subsequently, a pipe is connected to the switching valve 212a of the loading/unloading jig 200, and the switching valve 212a is manipulated so as to raise the loading/unloading jig 200 to the raised end. When the loading/unloading jig 200 is raised to the raised end, the cassette 50 placed on the receiving member 62 is transmitted onto the plurality of rollers 223.

Subsequently, the transporting device 300 is moved to the vicinity of the opening of the chamber 10, and the cassette 50 is drawn to the transporting device 300 from above the plurality of rollers 223.

In this manner, the cassette 50 may be unloaded from the inside of the chamber 10.

When detaching the loading/unloading jig 200 from the receiving member 62, the driving unit 210, the lifting unit 220, and the connecting unit 230 may be separated in the reversed procedure to the procedure described above. The driving unit 210, the lifting unit 220, and the connecting unit 230, which are separated from each other, may be detached from the receiving member 62. As a result, even in a case of the long loading/unloading jig 200, the handling or the storage is facilitated.

When a plurality of cassettes 50 is loaded or unloaded, the above-described procedure may be performed repeatedly.

Subsequently, a method for forming an organic film according to the embodiment will be described.

The method for forming the organic film according to the embodiment may have, for example, following steps. A step of loading the cassette 50 in which the workpiece 100 is supported into the chamber 10 of the heat treatment apparatus 1 by using the loading/unloading jig 200.

A step of supporting the workpiece 100 including a substrate and a solution applied to the surface of the substrate inside the cassette 50 having a box shape.

A step of forming an organic film on the surface of the substrate by heating the cassette 50 loaded into the chamber 10.

A step of cooling for lowering the temperature of the workpiece 100 on which the organic film is formed.

A step of unloading the workpiece 100 on which the organic film is formed from the cassette 50.

A step of unloading the cassette 50 from the chamber 10 of the heat treatment apparatus 1 to the outside by using the loading/unloading jig 200 described above.

A known technique may be applied to the heating conditions for the workpiece 100 and the cooling conditions for the workpiece 100. Further, the contents of each step may be the same as those described above. As a result, detailed description of each step will be omitted.

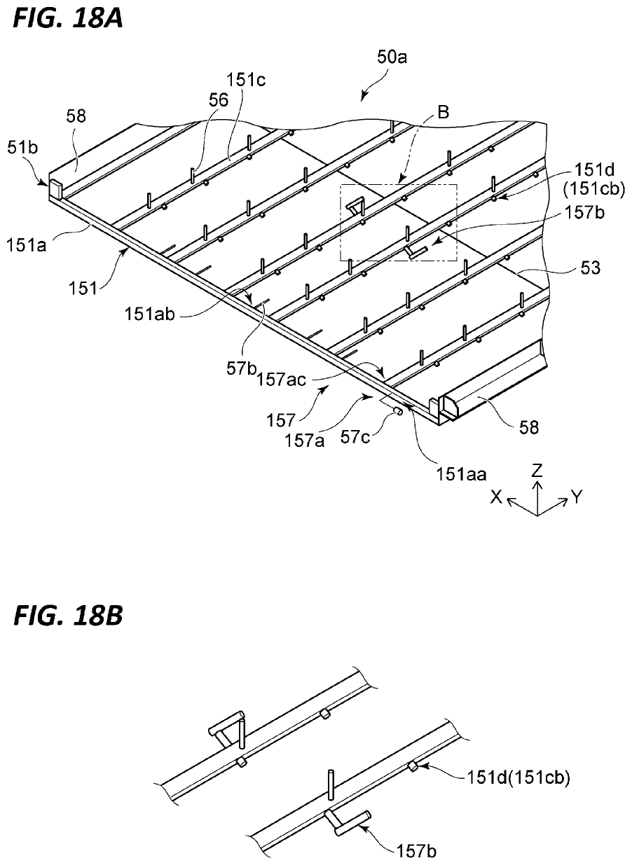

FIGS. 18A and 18B are schematic perspective views illustrating the inside of a cassette 50a according to another embodiment.

The cassette 50a includes, for example, a cassette frame 151, the upper soaking plate 52, the lower soaking plate 53, the side soaking plate 54, the side soaking plate 55, the workpiece support portion 56, a cooling unit 157, and the cassette support portion 58. That is, as compared to the cassette 50, the cassette 50a is different in the cassette frame 151 and the cooling unit 157.

In FIGS. 18A and 18B, in order to avoid complexity, the upper soaking plate 52, the side soaking plate 54, and the side soaking plate 55 are omitted.

The cassette frame 151 includes a frame-shaped member 151a, a beam 151c, the pillar 51b, the frame-shaped member 51a, the beam 51c, and a cap 151d. For example, in the Z-direction, the frame-shaped member 151a provided with the beam 151c is provided on the lower side, and the frame-shaped member 51a provided with the beam 51c is provided on the upper side. Therefore, as compared to the cassette frame 51, the cassette frame 151 is different in the frame-shaped member 151a, the beam 151b, and the cap 151d.

In FIGS. 18A and 18B, in order to avoid complexity, the upper frame-shaped member 51a is omitted.

The frame-shaped member 151a has a role that constitutes the lower surface of the processing space described above.

The frame-shaped member 151a has, for example, a rectangular frame shape. The frame-shaped member 151a is formed by, for example, combining a plurality of tubular bodies such as square pipes. That is, the inside of the frame-shaped member 151a is hollow. The frame-shaped member 151a is formed by, for example, welding a plurality of tubular bodies. The frame-shaped member 151a is made of, for example, metal such as stainless steel.

A hole 151aa to which a pipe 157a (to be described later) of the cooling unit 157 is connected is provided in a part of the side surface of the external side of the frame-shaped member 151a, for example, an outer peripheral surface included one side of the frame-shaped member 151a. A hole 151ab to which the nozzle 57b is connected and a hole 151ac to which the beam 151c is connected are provided in a part of the side surface of the internal side of the frame-shaped member 151a, for example, an inner peripheral surface included one side of the frame-shaped member 151a.

The beam 151c is a member configured to suppress the thermal deformation of the frame-shaped member 151a. The beam 151c is formed, for example, to connect the two sides of the frame-shaped member 151a facing to each other. The beam 151c is formed by, for example, a tubular body such as a square pipe. That is, the inside of the beam 151c is hollow. The beam 151c is, for example, attached to the hole 151ac of the frame-shaped member 151a by welding. As a result, the inside of the frame-shaped member 151a and the inside of the beam 151b are connected. The beam 151c is made of, for example, metal such as stainless steel. In the embodiment, six beams 151b are provided.

A plurality of holes 151cb in which a nozzle 157b (to be described later) is provided is provided on both side surfaces of the beam 151c. The nozzle 157b is not provided to all the holes 151cb provided on both side surfaces of the beam 151c. As a result, the cap 151d is provided to the hole 151cb to which the nozzle 157b is not connected.

The cap 151d has a function of air-tightly blocking the hole 151cb to which the nozzle 157b is not connected. The cap 151d is, for example, a fixing screw or a sunken plug. A female screw is put in the hole 151cb, and then, the cap 151d is screwed into the hole 151cb. In this manner, the hole 151cb may be air-tightly blocked. The cap 151d is made of, for example, metal such as stainless steel.

The cooling unit 157 is provided in the cassette frame 151.

As illustrated in FIGS. 18A and 18B, the cooling unit 157 includes, for example, the pipe 157a, the nozzle 57b, the nozzle 157b, and the joint 57c.

The pipe 157a is a pipe configured to supply the cooling gas supplied from the cooling unit 40 described above into the frame-shaped member 151a. The pipe 157a is, for example, an L-shaped pipe. The pipe 157a is attached to one side surface of the cassette frame 151 in the Y-direction. Specifically, the pipe 157a is attached to the hole 151aa of the frame-shaped member 151a. The joint 57c is connected to the end portion of the pipe 157a in the X-direction.

The length of the pipe 157a may be short as compared to the length of the pipe 57a. As a result, the heat capacity of the pipe 157a may be smaller than the heat capacity of the pipe 57a. Therefore, the speed at which the pipe 157a is cooled by the cooling gas is improved from the cooling speed of the pipe 57a. As a result, the cooling time of the workpiece 100 may be shortened. Further, when the pipe 157a is provided, the space of the cooling unit 157 may be saved. Further, the cooling gas flows from the pipe 157a to the inside of the frame-shaped member 151a. As a result, the speed at which the frame-shaped member 151a and the beam 151c are cooled is improved from the cooling speed of the frame-shaped member 51a and the beam 51c. As a result, it is possible to suppress the amount of heat transferred from the cassette 50a to the workpiece 100 by radiation. Therefore, the cooling time of the workpiece 100 may be shortened.

The cooling gas supplied to the inside of the frame-shaped member 151a is supplied to the nozzle 57b through the hole 151ac of the frame-shaped member 151a. The nozzle 57b plays the role which is the same as in the case of the cassette 50, and thus, detailed description thereof will be omitted.

The nozzle 157b is attached to the hole 151cb of the beam 151c. As a result, the cooling gas supplied to the inside of the frame-shaped member 151a is supplied to the nozzle 157b through the hole 151cb of the beam 151c. The nozzle 157b is provided inside the cassette 50a (cassette frame 151). The nozzle 157b is provided in the processing space described above. For example, similarly to the nozzle 57b, the nozzle 157b supplies the cooling gas to the back surface of the workpiece 100 supported in the internal space of the cassette 50a. The nozzle 157b may be inclined in the same direction as the nozzle 57b, with respect to the surface of the workpiece 100 to which the cooling gas is supplied. Further, the inclination angle of the nozzle 157b may be the same as or smaller than the inclination angle of the nozzle 57b.

The nozzle 157b is provided at a position closer to the center of the workpiece 100 as compared to the nozzle 57b. That is, when viewed from the direction perpendicular to the surface of the workpiece 100, a discharge port of the nozzle 157b may be provided at a position that is overlapping the workpiece 100. For example, in the length direction of the workpiece 100, the nozzle 57b may be provided on the external side of the workpiece 100 and the nozzle 157b may be provided on the internal side of the workpiece 100.

As described above, a plurality of holes 151cb of the beam 151c is provided on both side surfaces of the beam 151c. As a result, the attached position of the nozzle 157b may be adjusted. As a result, the temperature of the region in which the lowering of the temperature is insufficient with the cooling gas ejected from the nozzle 57b may be lowered by the cooling gas ejected from the nozzle 157b. Further, the flowing directions of the cooling gas supplied from each of the nozzles 57b and 157b are substantially the same. As a result, the lowering of the flow velocity of the cooling gas ejected from the nozzle 57b or the occurrence of stagnation thereof may be suppressed. That is, the heated workpiece 100 may be quickly and also uniformly cooled.

In the above, embodiments have been described. However, the present disclosure is not limited those techniques.

With respect to the above-described embodiments, appropriate design changes made by those skilled in the art are also included in the scope of the present disclosure as long as they have the features of the present disclosure.

For example, the shape, the size, and the arrangement of the heat treatment apparatus 1 are not limited to those illustrated, and can be changed as appropriate.

Further, each element provided in each of the embodiments described above can be combined as much as possible, and a combination thereof is also included in the scope of the present disclosure as long as it includes the features of the present disclosure.

What is claimed is:

1. A maintenance method of a heat treatment apparatus including a chamber having a box shape and provided with a heater, the maintenance method comprising:
attaching a loading/unloading jig to a receiver of the heat treatment apparatus that supports a cassette having a box shape and including a space in which a workpiece is supported, the loading/unloading jig including a roller on an upper portion and being configured to move the roller upward and downward;
transmitting the cassette supported by the receiver onto the roller by raising the loading/unloading jig;
unloading the cassette to an outside of the chamber by moving the cassette on the roller;
loading the cassette into the chamber by moving the cassette on the roller;
transmitting the cassette to the receiver by lowering the loading/unloading jig; and
detaching the loading/unloading jig from the receiver.

2. The maintenance method according to claim 1, wherein, in the loading the cassette, the cassette loaded into the chamber is different from the cassette unloaded in the unloading the cassette.

3. The maintenance method according to claim 1, wherein the unloading the cassette includes releasing a connection between a pipe of a cooler provided in the cassette and configured to supply a cooling gas into the cassette, and a supply pipe of the cooling gas provided in the heat treatment apparatus and connected to a gas source, and
the loading the cassette includes connecting the pipe of the cooler and the supply pipe to each other.

4. The maintenance method according to claim 1, wherein the transmitting the cassette onto the roller includes manipulating a switching valve connected to an air cylinder so as to raise the roller, the air cylinder being configured to drive a lifter provided in the loading/unloading jig and including the roller, and
the transmitting the cassette to the receiver includes manipulating the switching valve connected to the air cylinder so as to lower the roller.

5. The maintenance method according to claim 1, wherein the loading/unloading jig includes a plurality of lifters configured to raise the roller and a plurality of connectors configured to connect the lifters to each other, and
the attaching the loading/unloading jig includes connecting the plurality of lifters and the plurality of connectors to have a desired length according to the cassette.

6. A heat treatment apparatus comprising:
a chamber;
a cassette rack provided inside the chamber and including at least a pair of receivers;
a first heater provided above the pair of receivers and including at least one first sub-heater;
a second heater provided below the pair of receivers to face the first heater and including at least one second sub-heater; and
a cassette having a box shape and including a space in which a workpiece is supported, and detachably supported by the pair of receivers between the first heater and the second heater,
wherein a cassette support supported by the receiver is provided on each of a pair of side surfaces of the cassette, which face each other.

7. The heat treatment apparatus according to claim 6, wherein the receiver includes:
a first end portion provided on a side of the first heater and configured to support the cassette support of the cassette; and
a second end portion provided on a side of the second heater and facing the first end portion, and
wherein when viewed in a direction from the first end portion toward the second end portion, a tip end of the second end portion is positioned close to the side surface side of the cassette from a tip end of the first end portion.

8. The heat treatment apparatus according to claim 6, wherein the cassette further includes:
at least one nozzle provided inside the cassette and configured to supply a cooling gas to the workpiece; and
a tubular body connected to the nozzle and configured to cause the cooling gas to flow therethrough, and
wherein the tubular body constitutes a part of the cassette.

9. The heat treatment apparatus according to claim 7, wherein the cassette further includes:
at least one nozzle provided inside the cassette and configured to supply a cooling gas to the workpiece; and
a tubular body connected to the nozzle and configured to cause the cooling gas to flow therethrough, and
wherein the tubular body constitutes a part of the cassette.

10. The heat treatment apparatus according to claim 7, wherein a space is formed between the first end portion and the second end portion such that a loading/unloading jig used to load or unload the cassette is attached thereto or detached therefrom.

11. The heat treatment apparatus according to claim 9, wherein a space is formed between the first end portion and the second end portion such that a loading/unloading jig used to load or unload the cassette is attached thereto or detached therefrom.

12. The heat treatment apparatus according to claim 8, wherein a discharge port of the nozzle is provided such that the cooling gas discharged from the nozzle is supplied to a vicinity of an end of a back surface of the workpiece supported inside the cassette, and
an angle between the discharge port and the back surface of the workpiece is more than 0° and 30° or less.

13. The heat treatment apparatus according to claim 9, wherein a discharge port of the nozzle is provided such that the cooling gas discharged from the nozzle is supplied to a vicinity of an end of a back surface of the workpiece supported inside the cassette, and
an angle between the discharge port and the back surface of the workpiece is more than 0° and 30° or less.
